(19) United States
(12) Patent Application Publication
(10) Pub. No.: US 2010/0021632 A1
(43) Pub. Date: Jan. 28, 2010

(54) METHOD AND DEVICES FOR THE APPLICATION OF TRANSPARENT SILICON DIOXIDE LAYERS FROM THE GAS PHASE

(76) Inventors: Andreas BIEDERMANN, Ostrach (DE); Bianca BIEDERMANN, Ostrach (DE)

Correspondence Address: BURR & BROWN, PO BOX 7068, SYRACUSE, NY, 13261-7068, US

(21) Appl. No.: 12/554,101

(22) Filed: Sep. 4, 2009

Related U.S. Application Data
(63) Continuation of application No. PCT/DE2008/000392, filed on Mar. 5, 2008.

(30) Foreign Application Priority Data
Mar. 5, 2007 (DE) 10 2007 010 995.6

(51) Int. Cl. C23C 16/40; C23C 16/00

(52) U.S. Cl. 427/255.37; 118/715

(57) ABSTRACT

Method and device for the application of transparent silicon dioxide layers from the gas phase, in which precursors are introduced into an oven by means of a carrier gas, characterized in that a liquid-phase process takes place upstream of the gas-phase process, the liquid-phase process used being a process which would take place as a quasi-sol-gel process from silicon-containing starting chemicals up to the formation of a silicon dioxide gel, but the liquid-phase process is stopped in the batch of the sol state by vaporizing the reaction mixture with the precursors present, mixing it with the carrier gas and transporting it to the oven.

### CROSS REFERENCE TO RELATED APPLICATIONS

This application is a continuation of International Application No. PCT/DE2008/000392, filed Mar. 5, 2008, which designated the United States, and claims the benefit under 35 USC §119(a)-(d) of German Application No. 10 2007 010 995.6 filed Mar. 5, 2007, the entireties of which are incorporated herein by reference.

### FIELD OF THE INVENTION

The invention relates to a method and devices for the application of transparent silicon dioxide layers from the gas phase. Such layers can be used, for example, in order to protect articles from corrosion, in order generally to build up a barrier against undesired diffusion and/or in order to carry out optical functions as interference layers. Silicon dioxide layers are highly welcome and are frequently used also for the purpose of electrical insulation when high breakdown field strengths are to be achieved.

### BACKGROUND OF THE INVENTION

The processes on surfaces are very important in industry.

All reactions of the material of an article with surrounding materials require a transport process over the surface. Properties of the surface therefore decisively determine the utility value of an article.

Protective layers are often used in industry, from coatings to very thin electrolytically deposited noble metal layers. However, a satisfactory solution does not exist for all applications. It does not exist in particular when complicated shapes, such as, for example, bodies having undercuts, inner walls of cavities or small pigment bodies in a powder, have to be coated but at the same time extreme requirements are set with regard to the quality of the layers and/or the protective layer is required to remain as far as possible invisible. Precisely in the case of the largest field of use, the consumer goods, extremely low coating costs are demanded, so that some products exist for which a protective coating is urgently desired or would even be required but no protective coating is applied because it has not been possible to date to meet one or more of the abovementioned requirements.

Barrier layers are likewise becoming important, for example for the inhibition of growth (cf. DE 102 31 731 A1). Barrier layers are also successfully used in photocatalytic applications. An overview in this respect can be found in D. Bahnemann: Photocatalytic Detoxification of Polluted Waters (The Handbook of Environmental Chemistry, Springer Publishing 1999, Volume 2, Part L, 285-351). Reference is made to the corresponding contents of the publications for the present invention.

In recent years and decades, extensive research and technological developments were carried out in the area of thin films. A multiplicity of methods exist: vacuum vapor deposition, vacuum atomization (sputtering), vacuum plasma chemical vapor deposition (plasma-CVD), dipping, spraying, spin-coating, chemical decomposition in the gas phase, plasma spraying, flame coating, physical condensation with subsequent chemical reaction, thermal decomposition on the surface with many respective modifications. With sufficiently great effort, it is certainly possible to apply a protective layer to virtually any article by any of said methods, but the effort may often be economically unacceptable for the corresponding products.

The technical field of coating from the gas phase, which is considered here, is generally known and of considerable technological importance. Only the methods which enable any shapes to be coated and the coating to be carried out as economically as possible are therefore to be considered here. Gas-phase methods which can take place under atmospheric pressure, also abbreviated to APCVD (atmospheric pressure chemical vapor deposition), are certainly advantageous for this purpose.

In the technical literature Vakuumbeschichtung [Vacuum coating]/5. Anwendungern [Applications]—Part II, ISBN 3-18-401315-4, VDI-Verlag [VDI Publishing], page 200, gas-phase methods are classified according to deposition temperature as:

high-temperature CVD for T>900° C.

medium-temperature CVD for 600° C.<T<900° C.

low-temperature CVD for 600° C.<T.

A very detailed overview of the prior art in the case of these methods is contained in DE 197 08 808 A1, to which reference is hereby made.

Pyrolysis will be considered as a first method. Pyrolysis is based on the fact that silicon readily forms links to organic groups, giving rise to the entire class of substances comprising the silanes, in which many compounds have a significant vapor pressure. It is obvious that, at a sufficiently high temperature in an oxidizing atmosphere, the organic groups can be “burnt off” while the silicon remains as silicon oxide. Unfortunately, the pyrolysis of readily available silanes, such as tetraethoxysilane or hexamethyldisilane, requires high temperatures of above 700° C., as disclosed in A. C. Adams et al., Journal Electrochemical Society, Vol. 126, 1979, page 1042. In addition, there is evidence that the deposition takes place very inhomogeneously as described in Surya et al., Journal Electrochemical Society, Vol. 137, 1990, page 624, so that the pyrolysis has serious disadvantages for the abovementioned applications.

In DE 197 08 808 A1, further methods are analyzed, some are ruled out owing to severe grave disadvantages and in the end silicon tetraacetate is used as a precursor, the suitability of which in principle has already been described in Maruyama et al., Japanese Journal of Applied Physics, Vol. 28, 1989, L 2253. Here, a precursor is to be understood as meaning the substance which, as a volatile substance, is converted into the gas phase, i.e. must be capable of vaporization without residue, and is a possible material carrier for the desired coating in the chemical vapor deposition (CVD) coating method.

In contrast to the description in Maruyama et al., the silicon tetraacetate according to DE 197 08 808 A1 is freshly synthesized and immediately vaporized—even before crystallization—so that a substantially higher vapor pressure of the precursor can be reached before it itself decomposes. Only with the invention described in DE 197 08 808 A1 was it possible to achieve a technically feasible coating that in the meantime has a multiplicity of applications. It is in any case a low-temperature CVD; moreover, coating can be effected even below 300° C.

In the implementation of the invention described in DE 197 08 808 A1, it is of course possible for peculiarities to occur which give rise to technical difficulties and to this extent are felt to be a disadvantage.

DE 197 08 808 A1 discloses a method for the application of transparent protective layers to articles, which is carried out in undried air at atmospheric pressure and at a temperature of less than 500° C. in an oven. A second gas stream which contains a compound of silicon and a monocarboxylic acid at a vapor pressure greater than 2 mmHg and which is produced by vaporization of a liquid which contains the compound of silicon and a monocarboxylic acid in noncrystalline form is mixed with the undried air, and a liquid that neither reacts with the compound of silicon and a monocarboxylic acid nor participates in the deposition of the transparent protective layer is used. Preferably, the monocarboxylic acid used is acetic acid and accordingly silicon tetraacetate occurs as the compound of silicon and the monocarboxylic acid. It is evident that “a compound of silicon and a monocarboxylic acid” means a tetravalent compound typical of silicon, e.g. silicon tetraacetate.

However, the preparation of pure tetravalent compounds, such as silicon tetraacetate, is not trivial. A reaction using silicon tetrachloride, acetic acid and acetic anhydride is proposed in DE 197 08 808 A1.

Specifically, the use of silicon tetrachloride gives rise to problems which should not be underestimated from the technical point of view: silicon tetrachloride reacts violently with water, and acquires water wherever it can, in particular and precisely from the air. This means all replenishing and transfer processes must be effected carefully and with substantial exclusion of ambient air. Nevertheless, the formation of (hydrochloric acid-containing) silicon oxides (hydrates) is frequently observed at valves and seals. Moreover, silicon tetrachloride has a very high vapor pressure of 257 hPa at 20° C., so that, simply because of the considerable evolution of hydrochloric acid vapors, it is classified as being very hazardous to health and environmentally polluting, as evidenced by the following excerpt—Excerpt from SiCl4 safety data sheet:

“R Phrases: R14-35-37
Reacts violently with water. Causes severe burns. Irritating to respiratory system.

S Phrases: S7/9-26-36/37/39-45
Keep the container tightly closed in a well ventilated place. In case of contact with eyes, rinse immediately with plenty of water and seek medical advice. During work, wear suitable protective clothing, protective gloves and safety goggles/face protection.

Toxicological Data
after inhalation: extreme irritation of the respiratory tract
after skin contact: burns.
after eye contact: burns. Danger of blindness!
After swallowing: irritation of the mucous membranes in the mouth, throat, esophagus and intestinal tract. For esophagus and stomach, there is a risk of perforation.
After absorption of toxic amounts: cardiovascular disturbances.
Symptoms may occur after a time delay.
LC5O 60 mg/l inhalation, rat.

Ecological Data
Forms toxic decomposition products with water.
The following is generally true for HC1: harmful effect on water organisms. Harmful effect due to pH shift.

Biological Effects:
hydrochloric acid and hydrochloric acid formed by reaction: lethal from 25 mg/l for fish; Leuciscus idus LC5O: 862 mg/l (1 N solution)
Harmfulness limit: plants 6 mg/l.
Does not cause any biological oxygen depletion.
Do not allow to enter bodies of water, wastewater or soil!”

### SUMMARY OF THE INVENTION

It is now an object of the invention to provide a method and devices for the application of transparent silicon dioxide layers from the gas phase which, in comparison with silicon tetrachloride, use only harmless and technically easily handled synthesis chemicals and operate as low-temperature CVD with deposition temperatures T<600° C., as far as possible T<300° C.

Coating from the gas phase probably takes place by a plurality of intermediate compounds, a plurality of reaction steps being required for this purpose. Such reaction steps were very extensively investigated for the decomposition of diacetoxydi-tert-butoxysilane (DADBS) by way of example in Hofman, Dissertation “The Protection of Alloys . . . ”, University of Twente, ISBN 90-9005832-X. The sequence through intermediate compounds is in general to be presumed, even if the specific intermediate compounds for specific precursors were as a rule unlikely to be definitely known. It is also to be presumed that the reaction conditions may influence the reaction mechanism, so that, even for a certain precursor, different intermediate compounds may play a role under changed conditions.

In principle, the slowest reaction step for the formation of a required intermediate compound will substantially influence the deposition rate of the CVD process. In the case of “pure” CVD processes, reaction steps which either require high temperatures or otherwise take place extremely slowly can obviously occur. This is the case in particular with readily available and relatively harmless silanes as precursors.

The basis of the invention is the idea of accelerating the slow CVD reaction steps in another process in order only thereafter to carry out a gas-phase deposition with the already formed intermediate products.

A frequently used, relatively harmless and economical compound, tetraethoxysilane (TEOS), is used here as starting material. However, all silicon-containing compounds are in principle initially suitable. TEOS begins significant layer formation in gas-phase processes only at above 700° C. as described in Adams et al. In a sol-gel process, layer formation is, however, carried out at as low as room temperature.

According to the invention, it is now proposed to carry out a combination of a sort of “sol-gel process” in a reactor and thereafter the CVD in such a way that the “sol-gel process” is stopped in the batch in an early sol state and immediately converted into a gas-phase process. Neither a sol nor a gel state is permitted to form here. The sol-gel formation reaction can take place only if no vaporization of the compound occurs. The reaction is thus stopped in the initial phase of chemical derivatization in a state prior to coagulation by vaporizing the corresponding compound. According to the invention, the time should be chosen sufficiently early so that intermediate products, still in the form of precursors, can be transferred from the quasi-sol reaction mixture to the gas phase. A basis of the consideration is that the sol reaction mixture has a multiplicity of products and intermediate products (generally of unknown type) but, for the layer formation from the gas phase, only the intermediate products which also rapidly form a layer are effective. The other (ineffective) substances will leave the CVD reactor.

Sol-gel processes are frequently initiated by pH shift. Quasi-sol-gel processes which give transparent layers are described, for example, in DE 41 17 041 A1. The processes can be started by addition of alkalis or acids. According to the invention, a volatile acid is particularly suitable since it can then also be vaporized.

DE 41 17 041 A1, however, mentions reaction times of two days (example 1). The difference compared with the present invention is particularly substantial owing to the required time. In the present invention, reaction times of a few multiples of 10 minutes are typical and the intermediate products can be additionally vaporized. In contrast, after a longer reaction time, such as, for example, in DE 41 17 041 A1, the intermediate products are formed with higher molecular weights and can no longer be vaporized.

### BRIEF DESCRIPTION OF THE DRAWINGS

For a fuller understanding of the nature and objects of the invention, reference should be made to the following detailed description of the invention, read in connection with the accompanying drawings in which:

FIGS. 1 and 2 show the cross sections of reactors 40 for the liquid-phase processes; and

FIG. 3 is a graph showing the dependency of growth rate on the concentration of the acetic acid.

### DETAILED DESCRIPTION OF THE INVENTION

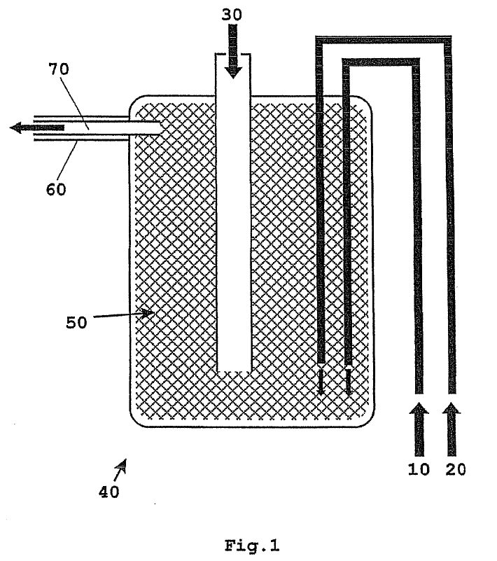

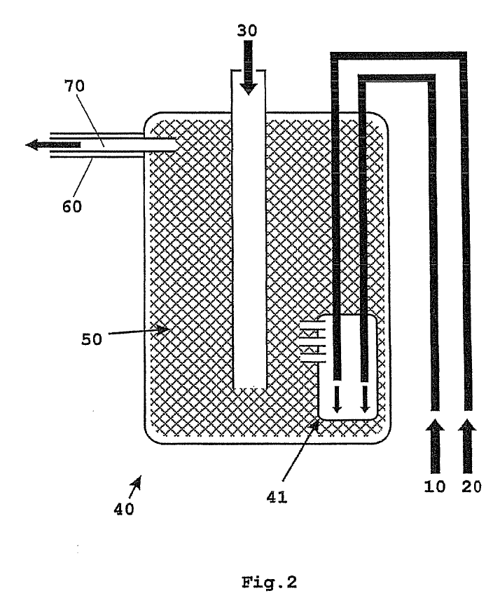

An embodiment of the invention is to be illustrated with reference to the figures. FIGS. 1 and 2 show the cross sections of reactors 40 for the liquid-phase processes. At 10, the silicon-containing chemical, e.g. tetraethoxysilane or a mixture of silicon-containing chemicals is introduced. At 20, the chemical for starting the quasi-sol-gel reaction is introduced, e.g. acetic acid but also ammonia can be used. Overall, a liquid mixture is present in the interior of the reactor, even if certain chemicals, such as, for example, ammonia, can be introduced in gaseous form and only thereafter dissolve in the mixture. The introduction of water is not shown separately but water can be fed in separately or as a constituent in 10 or 20, but also as a constituent of the carrier gas 30.

A catalyst 50, as a wire ball here, may advantageously be arranged in the interior of the reactors for the liquid-phase processes. The catalyst accelerates the liquid-phase processes and thus reduces the required average residence time in the liquid state. The activity of platinum catalysts is proven, but nickel-containing catalysts may also be used.

The temperature of the reactors 40 can be regulated and the liquid-phase processes can be carried out between room temperature and boiling point, the partial pressure of the precursors in the vaporized reaction mixture 70 depending both on the reactor temperature and on the average residence time of the liquid, reactor temperatures above 40° C. proving advantageous in many cases. If a reactor temperature above room temperature is set, the (pipe, hose) line for the vaporized mixture 70 must be kept at a temperature above the reactor temperature, for example 10° C. above, by a heating device 60, in order to prevent condensation of the vaporized reaction mixture. The vaporized reaction mixture 70 is introduced into an oven in which the substrates to be coated are present (not shown here) and in which the customary CVD process then takes place. The CVD process can take place here under atmospheric pressure, so that as a rule the oven requires no particularly complicated seals. However, it is to be assumed that a coating process also takes place under other pressures, for example under reduced pressure.

Air can frequently be used as carrier gas, but also nitrogen or argon. The use of inert gases may be advantageous because there is then no longer any need to pay attention to falling below the ignition limit in the oven at the concentration of the vaporized mixture.

Extensive experience is available regarding the required oven temperature. It appears to be that a different oven temperature is optimum for different applications. It may be, for example, that a lower temperature (280° C.) is more advantageous for the requirement as regards uniform all-round coating for optical applications than for electrical insulation of sharp-edged parts (370° C.).

Interestingly, coating is possible down to 250° C.—perhaps even a few degrees lower, but the growth rate then decreases noticeably with decreasing temperature.

Overall, the upstream liquid-phase process naturally shows a complicated dependency on:

the chemicals used (silicon-containing substance and sol-gel starting substance)

the reactor temperature
the average residence time in the liquid phase, precisely the average residence time itself showing a complicated dependency on
   the inflow of chemicals
   the inflow of carrier gas
   the vapor pressure of the intermediate products and hence the progress of the quasi-sol process itself.

In the case of a predetermined industrial coating performance, a certain amount of silicon-containing starting chemicals must of course be fed in. Regulation can then be effected only via the temperature of the reactor 40 and to a certain extent via the feed of the carrier gas. This regulation is extremely complex, so that it is proposed to arrange, in the interior of the reactor 40, a prereactor 41 (FIG. 2) to be set to another (higher) temperature. The temperature of the prereactor provides a further degree of freedom for regulation of the process. In the prereactor, the first reaction steps can be accelerated. The actual vaporization, however, takes place only in the (large) reactor.

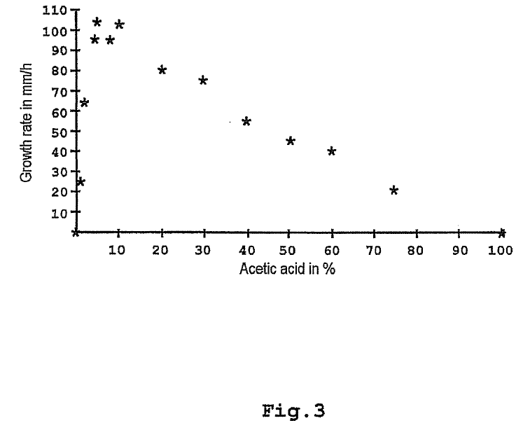

When carried out with tetraethoxysilane and acetic acid (containing about 10% of water), there is an interesting dependency of the growth rate on the concentration of the acetic acid, shown in FIG. 3. Other settings:

oven 350° C., 100 1

prereactor 60 cm³, 95° C.

reactor 11, 55° C.

carrier gas air, 60 cm³/s

pipe temperature 80° C.

The maximum growth rate is from 5% to 10% proportion of acetic acid. That no coating takes place at 0% and at 100% of acetic acid is understandable. However, that the maximum occurs at only from 5% to 10% proportion of acetic acid evidently shows that a stoichiometric tetraacetate reaction is not required.

An astonishing similarity of the characteristic 20 dependency on the concentration as in FIG. 3 is to be found in Fujino et al., Journal Electrochemical Society, vol. 137, 1990, page 2883: “Silicon Dioxide Deposition by Atmospheric Pressure and Low-Temperature CVD using TEOS and Ozone”. There, coating was also effected under atmosphere pressure and tetraethoxy-silane (TEOS) was also used; however, as a pure gas-phase method with the use of ozone and a temperature range somewhat higher at 400° C.

What is claimed:

1. A method for the application of transparent silicon dioxide layers from the gas phase, in which precursors are introduced into an oven by means of a carrier gas, wherein a liquid-phase process takes place upstream of the gas-phase process, the liquid-phase process used being a process which would take place as a quasi-sol-gel process from silicon-containing starting chemicals up to the formation of a silicon dioxide gel, but the liquid-phase process is stopped in the batch of the sol state by vaporizing the reaction mixture with the precursors present, mixing it with the carrier gas and transporting it to the oven.

2. The method for the application of transparent silicon dioxide layers from the gas phase as claimed in claim 1, wherein, as starting chemicals for the liquid-phase process, acids or alkalis are mixed with the silicon-containing starting chemicals.

3. The method for the application of transparent silicon dioxide layers from the gas phase as claimed in claim 1, wherein acetic acid, in particular acetic acid having a certain water content, is admixed as starting chemicals for the liquid-phase process.

4. The method for the application of transparent silicon dioxide layers from the gas phase as claimed in claim 1, wherein alcoholates of silicon are used as silicon-containing starting chemicals for the liquid-phase process.

5. The method for the application of transparent silicon dioxide layers from the gas phase as claimed in claim 1, wherein tetraethoxysilane is used as silicon-containing starting chemicals for the liquid-phase process.

6. A device for the application of transparent silicon dioxide layers from the gas phase, by which precursors are introduced into an oven by means of a carrier gas, comprising a reactor in which silicon-containing starting chemicals and starting chemicals for a quasi-sol-gel process are mixed and the reaction mixture is vaporized into the carrier gas is arranged before the oven in the direction of flow of the carrier gas.

7. The device for the application of transparent silicon dioxide layers from the gas phase as claimed in claim 6, wherein the reactor is heatable.

8. The device for the application of transparent silicon dioxide layers from the gas phase as claimed in claim 7, wherein the reactor is heatable to temperatures of from 30° C. to 150° C.

9. The device for the application of transparent silicon dioxide layers from the gas phase as claimed in claim 6, wherein a catalyst is arranged in the reactor, the catalyst advantageously being in the form of a wire ball and advantageously consisting of a platinum-containing and/or nickel-containing material.

10. The device for the application of transparent silicon dioxide layers from the gas phase as claimed in claim 6, wherein the reactor has a prereactor that is heatable to a temperature which is higher than the reactor temperature.

11. The device for the application of transparent silicon dioxide layers from the gas phase as claimed in claim 6, wherein the reactor has an exit line to the oven for the vaporized reaction mixture, which exit line is heatable to a temperature which is higher than the reactor temperature.
